(19) United States
(12) Patent Application Publication
(10) Pub. No.: US 2007/0140512 A1
(43) Pub. Date: Jun. 21, 2007

(54) Signal processing for hearing devices having a number of compression algorithms

(75) Inventors: Jens Hain, Kleinsendelbach (DE); Andre Steinbuss, Nurnberg (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Audiologische Technik GmbH

(21) Appl. No.: 11/642,109

(22) Filed: Dec. 20, 2006

(30) Foreign Application Priority Data
Dec. 20, 2005 (DE) 10 2005 061 000.5

(51) Int. Cl. H03G 7/00; H03G 9/00

(52) U.S. Cl. 381/106; 381/321; 381/102

(57) ABSTRACT

The signal processing, in particular of hearing devices, is to be improved in a situation-dependent manner. Provision is thus made for classifying an input signal in respect of the current hearing situation. As a function of the classification result, the input signal is amplified according to a first compression algorithm or a second compression algorithm. This enables the respective advantages of the different compression algorithms to be used in the individual hearing situations.

### CROSS REFERENCE TO RELATED APPLICATIONS

This application claims priority of German application No. 10 2005 061 000.5 filed Dec. 20, 2005, which is incorporated by reference herein in its entirety.

### FIELD OF THE INVENTION

The present invention relates to a signal processing apparatus, particularly for a hearing device having a compression facility for amplifying an input signal according to a compression algorithm and having a classification facility for classifying the input signal in respect of the hearing situation. Furthermore, the present invention relates to a corresponding method for signal processing.

### BACKGROUND OF THE INVENTION

As a rule, the hard-of-hearing can only perceive a restricted range of levels of input signals. The overall input signal level range is thus to be transformed into this perceivable range of levels, a task which can be performed by so-called compression. With hearing devices, the signal processing compresses the input signals in order to carry out an adjustment to the modified dynamic range of the hard-of-hearing.

Different approaches currently exist for compressions. The realization of compression by an AGCi (Automatic Gain Control Input Dependent) is in widespread use. Its behavior can be described with the aid of a characteristic curve, which defines the functional relationship between the input and output levels. In such cases, one or a number of compression ratios define the curve shape of the compression. With several compression ratios, two compression lines merge into a so-called compression knee point. A continuous gain curve is thus ensured as a function of the input level.

The gain is adaptively adjusted in a level-dependent manner according to another, alternative approach. A method of this type is known for instance by the name “ADRO compression” (Adaptive Dynamic Range Optimization). This compression method cannot be described with fixed compression knee points and/or compression ratios. Instead, the amplification is adaptively changed here if the output level exceeds a predetermined maximum level or fails to reach a predetermined minimum level.

A detailed examination has however shown that neither of the two methods, AGCi nor ADRO, is advantageous for all hearing situations.

The publication DE 197 03 228 A1 solves this problem in a rudimentary manner, in that an input-related compression (AGCi) is supplemented by an upstream situation analysis. Depending on the result of the situation analysis, the behavior of the AGCi is varied in knee point and compression ratio in order to achieve the highest possible performance in each situation.

Furthermore, the publication EP 1 307 072 A2 discloses a method for operating a hearing device, with which disruptive acoustic effects caused by turn-on, turn-off and or changeover processes are to be prevented. To this end, the signal processing in the hearing device is transferred smoothly from a first operating state into a second operating state. The smooth transfer is carried out by a parallel signal processing in at least two signal paths of the hearing device, with a signal resulting from the first operating state, and a signal resulting from the second operating state, being added with alternating weighting. A smooth transfer can thus be achieved by changing a compression characteristic curve for instance.

### SUMMARY OF THE INVENTION

The object of the present invention is thus to propose a signal processing apparatus, which, can be used as a shared method for different hearing situations to provide enhanced quality. Furthermore, a corresponding signal processing method is to be specified.

In accordance with the invention, this object is achieved by a signal processing apparatus, in particular for a hearing device, having a first compression facility for amplifying an input signal corresponding to a first compression algorithm and a classification facility for classifying the input signal in respect of the hearing situation, as well as at least one second compression facility for amplifying the input signal corresponding to at least one second compression algorithm, with the input signal be able to be conveyed by the classification facility as a function of the classification to the first or second compression facility.

Furthermore, a method is provided in accordance with the invention for signal processing, in particular in a hearing device, as well as for amplifying an input signal according to a first compression algorithm and classifying the input signal in respect of the hearing situation and amplifying the input signal according to at least one second compression algorithm, said amplification being carried out as a function of the classification result (either) in accordance with the first or the second compression algorithm.

A selection is thus advantageously made from the respective optimal compression algorithm or the optimal compression algorithms depending on the hearing situation. A situation-dependent parameterization, which results in less than optimum results, is not the only process carried out.

With the first compression algorithm, the output level preferably always increases continuously with the input level. This is usually the case with AGCi algorithms.

Expediently, with the second compression algorithm, the output level is always kept below a maximum level and above a minimum level irrespective of the input level. With the ADRO algorithm, this is achieved by adding or subtracting a gain offset when the level range boundary is reached. If necessary, the addition or subtraction of the offset can be repeated several times so that the output signal remains in the desired level range. With a special embodiment, both compression algorithms, sometimes even more, are implemented on a single chip, thereby not increasing the hardware complexity.

The changeover between the two compression algorithms can be carried out smoothly by the classification facility. This is advantageous in that the hearing device wearer does not or barely perceives the change. Furthermore, the classification facility can comprise a trigger input, by way of which the compression algorithm can be changed via an external signal. This results in the advantage that the compression algorithm can be also be changed over by a trigger signal which is external to the signal processing, e.g. pressing a button on the hearing device.

The inventive signal processing apparatus and the corresponding method is preferably used in a hearing device, but can likewise be used in other hearing apparatuses, such as headsets.

### BRIEF DESCRIPTION OF THE DRAWINGS

The present invention is now described in more detail below with reference to the appended drawings, in which;

FIG. 1 shows main circuit diagram of a hearing device according to the invention;

FIG. 2 shows an amplification characteristic curve for an AGCi method;

FIG. 3 shows an input signal level shape;

FIG. 4 shows an output signal level shape for a hearing situation with AGCi processing and

FIG. 5 shows an output signal level shape for a hearing situation with ADRO processing

### DETAILED DESCRIPTION OF THE INVENTION

The exemplary embodiment illustrated in more detail below represents a preferred embodiment of the present invention.

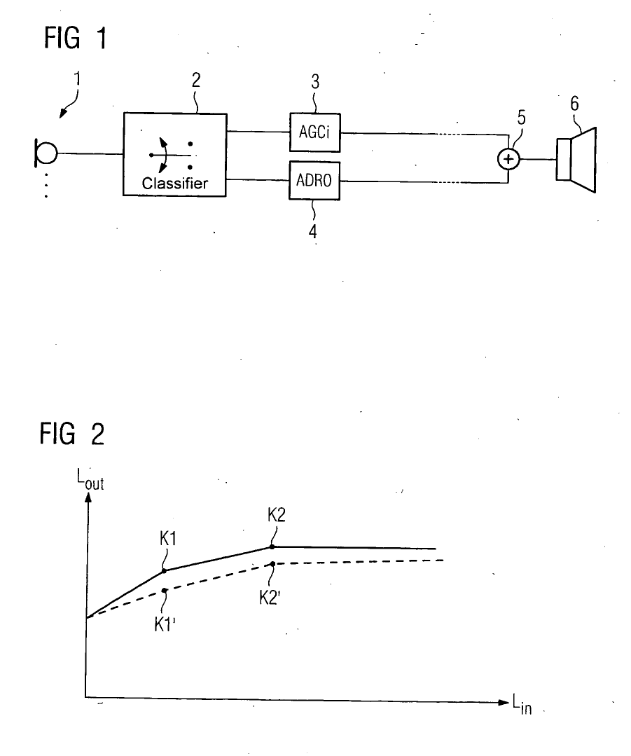

An inventive hearing device according to the example in FIG. 1 consists of one or a number of microphones 1, which are connected to a classifier 2. The classifier analyses the input signal from the microphone(s) 1 and connects the input signal to a one of the relevant several outputs. One of the outputs is connected here to an AGCi module 3 and the other output is connected to an ADRO module 4. The output signals of the two amplifier modules 3, 4 are further processed if necessary and are combined in a cumulative element 5. The output signal of the cumulative element 5 is finally fed to a loudspeaker 6.

In the selected example, the individual elements 2, 3, 4 are described as separate hardware components. These components can however also be implemented on a single chip and/or as individual software modules. In this way, the classifier 2 generates a control signal, with which either an AGCi module or an ADRO module is accessed to process the input signal.

Irrespective of the type of realization, two or more compression algorithms are implemented in each case in the hearing device and/or hearing apparatus. Based on the result of a situation analysis by the classifier 2, the hearing device automatically switches between the two implemented compression approaches in as smooth a fashion possible so as to be able to use the advantages of the respective method in every situation. Not just one parameter of the single compression algorithm is adjusted as a function of the current hearing situation, but instead a switch is made between two or more dependent compression algorithms based on the result of a situation analysis.

In addition to the automatic changeover of the compression algorithm by the classifier 2 as a function of the respective situation, there is also provision for the changeover to take place in an event-triggered manner. By way of example, a triggering of this type could occur by activating a key on the hearing device or an external operating unit, e.g. remote control. The classifier 2, which also exhibits a switching or control functionality, therefore has an additional input, which accepts the trigger signal.

FIGS. 2 to 5 give practical examples of how the signal processing can be switched on the basis of the hearing situation. FIG. 2 first shows a gain curve of an ACGi as a solid line. This amplification curve shape is highlighted in the present example by three compression ratios (gradients of the characteristic curve). The compression characteristic curve exhibits a continuous shape and changes its gradient at the compression knee points K1 and K2.

With the prior art mentioned at the start, it is only possible to change the characteristic curve shape in a situation-dependent manner. Accordingly, the knee points can be changed in a special situation at points K1′ and K2′ (cf. FIG. 2) for instance. The compression algorithm nevertheless remains the same in such cases. This can result in a certain improvement, but is not helpful in many situations. In accordance with the invention, the overall compression algorithm is changed for this reason. Starting from the AGCi compression, a switch can be made to the ADRO compression for instance (cf. FIG. 1).

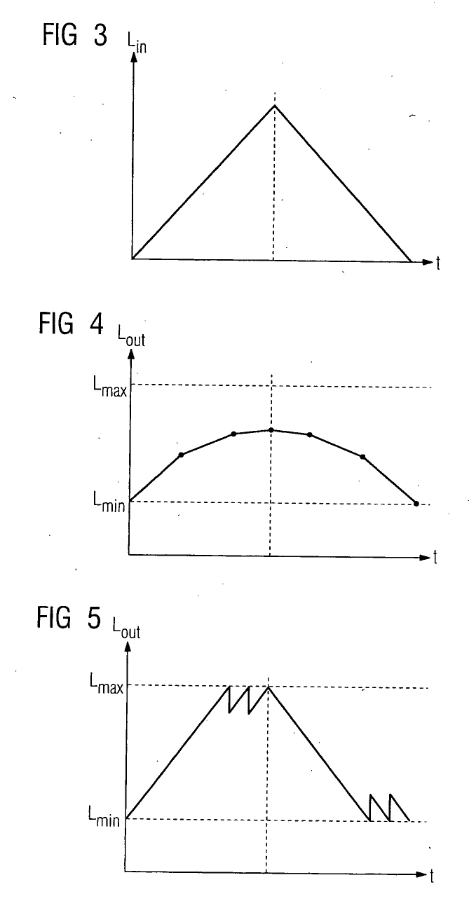

FIG. 3 illustrates a concrete input signal. Its signal curve is triangular in the example. A linear drop in the level occurs after a linear increase.

The classifier 2 first determines a situation, e.g. speech in quiet surroundings, in which a type of AGCi compression is advantageous. The characteristic curve in FIG. 2 is thus used to compress the input signal in FIG. 3. The output signal resulting therefrom is shown in FIG. 4. The overall dynamic range between a minimum level Lmin and a maximum level Lmax is not used here.

In another hearing situation, e.g. with music, the classifier switches to the ADRO compression. The input signal in turn exhibits the level curve shape shown in FIG. 3. The output level according to the ADRO compression is shown in FIG. 5. Accordingly, the output level Lout first increases until the maximum Lmax is reached. As the input level Lin increases further and the output level range is not to be left, an output level reduction by a predetermined value (offset) is carried out. The output level Lout also increases in turn and reaches the maximum level Lmax again due to the further increasing signal level Lin. The level reduction is repeated here by the predetermined offset value. This drop can be repeated several times.

When the input level Lin drops, a similar image is produced. The output level Lout also sinks first until a minimal level Lmin is reached. To ensure that the input sound remains audible to the hearing device wearer however, the output level is raised by a similarly constant value. In some circumstances, this can happen several times if the input level drops further. The entire output level range can be used in this way for part of the input level range.

The two compression algorithms AGCi 3 and ADRO 4 allow completely different output levels to be achieved as a function of the hearing situation. The advantages of different compression approaches can thus be combined in a single device, and their respective advantages used in the individual hearing situation.

1-10. (canceled)

11. A signal processing apparatus for a hearing device, comprising:
a first compression unit that amplifies an input signal of the hearing device corresponding to a first compression algorithm;
a second compression unit that amplifies the input signal of the hearing device corresponding to a second compression algorithm; and
a classification unit that classifies the input signal of the hearing device as a function of the first or the second compression algorithm based on a hearing situation.

12. The signal processing apparatus as claimed in claim 11, wherein the first compression algorithm continuously increases a level of an output signal with a level of the input signal over an entire range.

13. The signal processing apparatus as claimed in claim 11, wherein the second compression algorithm maintains a level of an output signal below a maximum level and above a minimum level irrespective of a level of the input signal.

14. The signal processing apparatus as claimed in claim 11, wherein the first and the second compression algorithm is implemented on one chip.

15. The signal processing apparatus as claimed in claim 11, wherein a switchover between the first and the second compression algorithm is performed by the classification unit based on the classification.

16. The signal processing apparatus as claimed in claim 11, wherein a switchover between the first and the second compression algorithm is performed by the classification unit via an external signal.

17. A hearing device, comprising:
a microphone that generates an input signal;
a classifier connected to the microphone that classifies the input signal based on a hearing situation;
a first compression unit connected to the classifier that amplifies the input signal based on a first compression algorithm if the classifier classifies the input signal to the first compression algorithm;
a second compression unit connected to the classifier that amplifies the input signal based on a second compression algorithm if the classifier classifies the input signal to the second compression algorithm; and
a loudspeaker that outputs the amplified input signal.

18. The hearing device as claimed in claim 17, wherein the first compression algorithm continuously increases a level of the amplified input signal with a level of the input signal over an entire range.

19. The hearing device as claimed in claim 17, wherein the second compression algorithm maintains a level of the amplified input signal below a maximum level and above a minimum level irrespective of a level of the input signal.

20. The hearing device as claimed in claim 17, wherein the hearing device is a hearing aid device worn by a wearer.

21. The hearing device as claimed in claim 17, wherein the hearing device is a headset.

22. A method for processing an input signal in a hearing device, comprising:
implementing a first and a second compression algorithm in the hearing device;
classifying the input signal based on a hearing situation; and
amplifying the input signal according to the first or the second compression algorithm based on the classification.

23. The method as claimed in claim 22, wherein the first compression algorithm continuously increases a level of an output signal with a level of the input signal over an entire range.

24. The method as claimed in claim 22, wherein the second compression algorithm maintains a level of an output signal below a maximum level and above a minimum level irrespective of a level of the input signal.
